(19) United States
(12) Patent Application Publication
(10) Pub. No.: US 2026/0060071 A1
(43) Pub. Date: Feb. 26, 2026

(54) SEMICONDUCTOR DEVICE

(71) Applicant: WAVEPIA CO., LTD., Gyeonggi-do (KR)

(72) Inventors: Sang Hun LEE, Hwaseong-si (KR); Sang Yeol LEE, Hwaseong-si (KR); Sang Su KIM, Hwaseong-si (KR)

(73) Assignee: WAVEPIA CO., LTD., Gyeonggi-do (KR)

(21) Appl. No.: 19/220,220

(22) Filed: May 28, 2025

(30) Foreign Application Priority Data
Aug. 20, 2024 (KR) 10-2024-0110907

(51) Int. Cl. H01L 23/34; H10D 30/47; H10D 62/85

(52) U.S. Cl. CPC H01L 23/34; H10D 30/475; H10D 62/8503

(57) ABSTRACT

The present disclosure relates to a semiconductor device. A semiconductor device according to one embodiment of the present disclosure includes a lower metal layer, a substrate disposed on the lower metal layer, at least one transistor disposed on the substrate, an insulating layer disposed on the substrate and configured to cover the at least one transistor, an upper metal layer disposed on the insulating layer, a first via which includes a material having thermal conductivity, and a second via which includes a material having thermal conductivity, wherein a source electrode of the at least one transistor is connected to the lower metal layer through the first via and is connected to the upper metal layer through the second via.

### CROSS-REFERENCE TO RELATED APPLICATION

This application claims priority to and the benefit of Korean Patent Application No. 2024-0110907, filed on Aug. 20, 2024, the disclosure of which is incorporated herein by reference in its entirety.

### BACKGROUND

### 1. Field of the Invention

The present disclosure relates to a semiconductor device, and more particularly, to a semiconductor device having a heat dissipation function.

### 2. Discussion of Related Art

As technology advances in fields of electric vehicles, autonomous vehicles, wireless communications including 5G or 6G, satellite communication, and high-resolution radars, semiconductor devices used in these fields are also being developed to enable high-speed operation and high output. To improve the operating speed and output of semiconductor devices, transistors disposed in the semiconductor devices are switched at higher speeds, and larger currents flow in active regions of the transistors. In such a process, power consumed by a semiconductor device further increases, and thus an amount of heat generated by the semiconductor device also increases.

As an amount of heat generated by a semiconductor device increases, various parts of the semiconductor device may degrade due to stress caused by excessive temperature changes. For example, cracks may occur in each layer that constituting a semiconductor device, or cracks may occur between layers. Accordingly, the lifetime of the semiconductor device may be shortened, or switching performance may be degraded due to reduced electron mobility.

Accordingly, various structures have been proposed to effectively dissipate heat from semiconductor devices. However, in conventional semiconductor devices, heat cannot be directly dissipated from an active region, which is a heat source generating the highest heat in the semiconductor device, and heat has been dissipated at a die or package level. Accordingly, conventional semiconductor devices have a problem in that since heat cannot be quickly dissipated from an active region, lifetime is shortened, and radio frequency (RF) performance is degraded over time of use.

In addition, in conventional semiconductor devices, passages for conducting heat are narrow or complex, and the area of a heat sink that dissipates heat to the outside is narrow. Accordingly, conventional semiconductor devices have a problem of a low heat dissipation effect.

Accordingly, there is an urgent need to develop a semiconductor device with excellent heat dissipation performance by conducting heat generated in an active region in various directions and dissipating heat to the outside using a wide heat sink.

Meanwhile, the information in the background art described above was obtained by the inventors for the purpose of developing the present disclosure or was obtained during the process of developing the present disclosure. As such, it is to be appreciated that this information did not necessarily belong to the public domain before the patent filing date of the present disclosure.

### RELATED ART DOCUMENTS

### Patent Documents

(Patent Document 1) United States Patent Publication No. US 2020-0144969 (May 7, 2020)

### SUMMARY OF THE INVENTION

The present disclosure is directed to providing a semiconductor device of which heat dissipation performance is improved by dissipating internally generated heat from each of upper and lower metal layers having a large area.

The present disclosure is also directed to providing a semiconductor device in which heat in an active region is dissipated through a via disposed adjacent to the active region which is a heat source generating the greatest heat, thereby preventing the performance degradation of the semiconductor device and preventing a decrease in lifetime thereof.

The present disclosure is also directed to providing a semiconductor device having a small volume and low manufacturing costs by dissipating heat generated in a device by using components used in the operation of a transistor without using a separate additional component.

The present disclosure is also directed to providing a semiconductor device having a flat upper end shape so that when a plurality of semiconductor devices are coupled in a three-dimensional stacked structure, an upper end portion and a lower end portion of each of the plurality of semiconductor devices can be easily coupled.

The present disclosure is also directed to providing a semiconductor device having a small area and stable radio frequency (RF) performance by including a lower metal layer, transistors, and pads vertically disposed with at least one layer interposed therebetween.

The objects of the present disclosure are not limited to those described above, and other objects not described may become apparent to those of ordinary skill in the art based on the following descriptions.

According to an aspect of the present disclosure, there is provided a semiconductor device including a lower metal layer, a substrate disposed on the lower metal layer, at least one transistor disposed on the substrate, an insulating layer disposed on the substrate and configured to cover the at least one transistor, an upper metal layer disposed on the insulating layer, a first via which includes a material having thermal conductivity, and a second via which includes a material having thermal conductivity, wherein a source electrode of the at least one transistor is connected to the lower metal layer through the first via and is connected to the upper metal layer through the second via.

The semiconductor device may further include a resistor, a third via which includes a material having electrical conductivity, and a temperature measuring pad disposed on the insulating layer, and the resistor may be connected to the temperature measuring pad through the third via.

The semiconductor device may further include a fourth via which includes a material having thermal conductivity, and the resistor may be connected to the lower metal layer through the fourth via.

The semiconductor device may further include a fifth via which includes a material having thermal conductivity, and the resistor may be connected to the upper metal layer through the fifth via.

The resistor may be disposed in a layer of the substate in which an active region of the at least one transistor is formed.

The semiconductor device may further include a gate pad electrically connected to a gate electrode of the at least one transistor, and a drain pad electrically connected to a drain electrode of the at least one transistor, and the upper metal layer, the temperature measuring pad, the gate pad, and the drain pad may be disposed on the insulating layer.

The upper metal layer, the temperature measuring pad, the gate pad, and the drain pad may be spaced apart from each other, and an area of the upper metal layer may be half or more of an area of the substrate.

The substrate may include a compound.

A layer of the substrate in which an active region of the at least one transistor is formed may include gallium nitride (GaN).

### BRIEF DESCRIPTION OF THE DRAWINGS

The above and other objects, features, and advantages of the present invention will become more apparent to those of ordinary skill in the art by describing exemplary embodiments thereof in detail with reference to the accompanying drawings, in which:

FIG. 1 is a plan view of a semiconductor device according to one embodiment of the present disclosure;

FIG. 2 is a view for describing positions of a transistor and a resistor in the semiconductor device according to one embodiment of the present disclosure;

FIG. 3 is a cross-sectional view along dashed line III-III′ of FIG. 1;

FIG. 4 is a cross-sectional view of a semiconductor device according to another embodiment of the present disclosure; and

FIG. 5 is a cross-sectional view of a semiconductor device according to still another embodiment of the present disclosure.

### DETAILED DESCRIPTION OF EXEMPLARY EMBODIMENTS

The advantages and features of the present disclosure and methods of accomplishing the same will become apparent based on the following description of the embodiments in detail, taken in conjunction with the accompanying drawings. However, the present disclosure is not limited to the embodiments to be disclosed below and may be implemented in various different forms. The present embodiments are merely provided so that this disclosure will be complete and will fully convey the scope of the invention to those skilled in the art. That is, the present disclosure is only defined by the scope of the claims.

A shape, a size, a ratio, an angle, and a number disclosed in the drawings for describing embodiments of the present disclosure are merely examples, and thus, the present disclosure is not limited to the illustrated details. In addition, in describing the present disclosure, when it is determined that a specific description of a known related art unnecessarily obscures the gist of the present disclosure, the detailed description thereof will be omitted. The terms such as “including,” “having,” and “consist of” used herein are generally intended to allow other components to be added unless the terms are used with the term “only.” Any references to a singular form may include a plural form unless expressly stated otherwise.

Components are interpreted to include an ordinary error range even if not expressly stated. For example, unless otherwise explicitly stated, the term “same” does not mean exactly the same, but rather means “substantially the same” within a margin of error that a person skilled in the art may reasonably expect to encounter in practicing the present disclosure.

Although the terms first, second, and the like are used to describe various components, these components are not limited by these terms. These terms are merely used to distinguish one component from another. Therefore, a first component to be described below may be a second component within a technical concept of the present disclosure.

Unless otherwise specified, like reference numerals refer to like elements throughout the specification.

The features of various embodiments of the present disclosure can be partially or entirely adhered to or combined with each other and can be interlocked and operated in technically various ways as understood by those skilled in the art, and the embodiments can be carried out independently of or in association with each other.

In the present disclosure, when a plurality of components are connected, it should be understood that the components are connected not only directly to each other, but also indirectly connected to each other. Therefore, when a plurality of components are connected to each other, another component may be connected between the plurality of components.

In describing various embodiments of the present disclosure, when some components of an embodiment are substantially the same as or corresponding to some components of another embodiment described above, the description of the components may be omitted to provide a clear and concise description of the present disclosure. In addition, when some components have a symmetrical structure with other components, for example, an axial symmetry structure or a rotational symmetry structure, so that both components are substantially the same component but only differ in terms of direction or position, unless it is necessary to specify the present disclosure, descriptions of the components may be omitted for the sake of providing a clear and concise description of the present disclosure.

Hereinafter, the present disclosure will be described in detail with reference to the accompanying drawings.

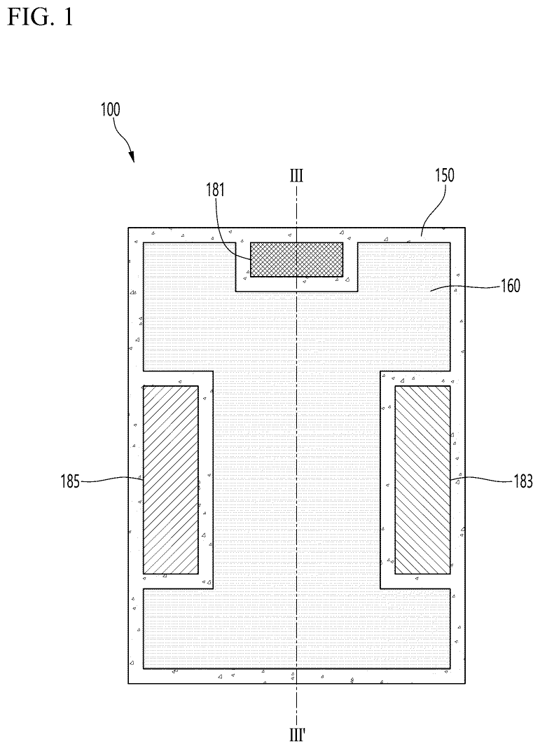

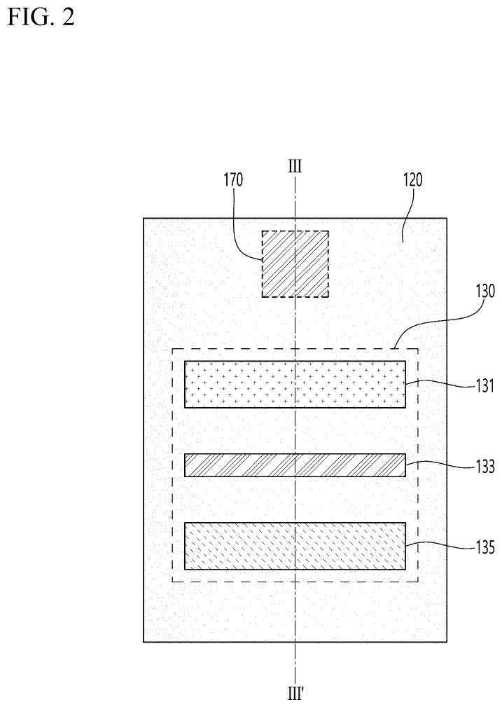

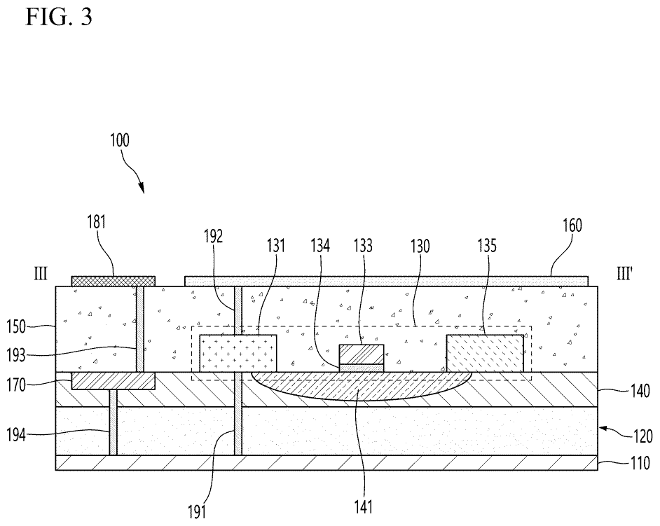

FIG. 1 is a plan view of a semiconductor device according to one embodiment of the present disclosure. FIG. 2 is a view for describing positions of a transistor and a resistor in the semiconductor device according to one embodiment of the present disclosure. FIG. 2 illustrates a structure of a semiconductor device 100 before an insulating layer 150 is stacked. Specifically, FIG. 2 is a plan view of a structure in which the insulating layer 150, an upper metal layer 160, a temperature measuring pad 181, a gate pad 183, a drain pad 185, a second via 192, and a third via 193 are removed from the semiconductor device 100 shown in FIG. 1. FIG. 3 is a cross-sectional view along dashed line III-III′ of FIG. 1.

Referring to FIGS. 1 to 3, the semiconductor device 100 includes a lower metal layer 110, a substrate 120, a channel layer 140 disposed on the substrate 120, at least one transistor 130, the insulating layer 150, the upper metal layer 160, a first via 191, and the second via 192. In some cases, the semiconductor device 100 may further include the temperature measuring pad 181, the gate pad 183, the drain pad 185, the third via 193, and a fourth via 194.

The semiconductor device 100 may be a power semiconductor used to process high power, high voltage, and high current. Specifically, the semiconductor device 100 may include a power semiconductor in which a plurality of semiconductor materials are bonded through a heterojunction. For example, the semiconductor device 100 may include a power semiconductor in which a plurality of semiconductor materials having different energy bandgaps, such as gallium nitride (GaN) and aluminum gallium nitride (AlGaN), are bonded through a heterojunction. However, the type of the semiconductor device 100 is not limited thereto. For example, the semiconductor device 100 may be a logic semiconductor designed for digital signal processing or may be a memory semiconductor used for storage and search for data.

Referring to FIG. 3, the lower metal layer 110 may be disposed at a lowermost end portion of the semiconductor device 100. The lower metal layer 110 may include a metal material. For example, the lower metal layer 110 may include at least one of metal materials such as gold, aluminum, copper, titanium, nickel, platinum, and molybdenum.

In addition, the lower metal layer 110 may be grounded. In this case, the lower metal layer 110 may function as a ground electrode of the transistor 130.

Referring to FIG. 3, the substrate 120 is disposed on the lower metal layer 110. For example, the substrate 120 may be disposed directly on the lower metal layer 110. The substrate 120 may include a channel layer 140 in which an active region 141 is formed as the transistor 130 operates. Alternatively, the channel layer 140 in which the active region 141 is formed may be further disposed on the substrate 120. Although not shown in FIG. 3, the substrate 120 may further include various layers in addition to the channel layer 140, or various layers other than the channel layer 140 may be further disposed thereon. For example, the substrate 120 may further include a body layer for mechanically supporting the overall structure, a buffer layer for relieving stress, a drift layer for voltage drop when a current flows, and an epitaxial layer for controlling electrical characteristics of a device.

The substrate 120 includes a semiconductor material. That is, the substrate 120 may be made of at least one semiconductor material. For example, the substrate 120 may be made of one semiconductor material or may include a compound consisting of two or more different elements. In this case, the substrate 120 may include a material such as gallium arsenide (GaAs), silicon carbide (SiC), or gallium nitride (GaN).

In particular, when the channel layer 140 in which the active region 141 is formed includes GaN, the semiconductor device 100 may perform fast switching due to high electron mobility, may process high power due to high electric field intensity and thermal conductivity, and may operate at a high temperature due to high thermal stability. High-speed, high-power, high-performance semiconductor devices may be manufactured, and heat generation problems occurring in such semiconductor devices may be alleviated through various embodiments of the present disclosure.

Referring to FIGS. 2 and 3, the transistor 130 is disposed on the substrate 120. For example, the transistor 130 may be disposed directly on the substrate 120. The transistor 130 may be a high electron mobility transistor (HEMT). In this case, since the transistor 130 provides high-speed switching performance and high current density, the semiconductor device 100 may exhibit excellent performance in power amplification and high-frequency applications. However, the type of the transistor 130 is not limited thereto. For example, the transistor 130 may be a junction field effect transistor (FET) (JFET), a metal oxide silicon field effect transistor (MOSFET), or a GaN FET. In particular, since the channel layer 140 of the transistor 130 is made of the above-described GaN, the transistor 130 may provide high-speed switching performance and high current density, and heat generation of the semiconductor device 100 may also be reduced through various embodiments of the present disclosure.

Although one transistor 130 is shown in FIG. 3, the number of transistors 130 is not limited thereto. For example, the semiconductor device 100 may include at least one transistor array (not shown) in which a plurality of transistors 130 are arrayed. In this case, the transistor array (not shown) may have a form in which a plurality of source electrodes 131 and a plurality of drain electrodes 135 are alternately disposed and a gate electrode 133 is arranged between each source electrode 131 and each drain electrode 135. In addition, the transistor array (not shown) may include gate lines (not shown) and drain lines (not shown) which apply an electrical signal to each of electrodes and are disposed in a direction perpendicular to a direction in which each of the electrodes extends.

Referring to FIGS. 2 and 3, the transistor 130 may include the source electrode 131, the gate electrode 133, and the drain electrode 135. The source electrode 131 and the drain electrode 135 may be spaced apart from each other with the gate electrode 133 interposed therebetween. In addition, the source electrode 131 and the drain electrode 135 may be made of the same material. In addition, at least a portion of each of the source electrode 131 and the drain electrode 135 may be ohmic-contacted to the substrate 120. In this case, resistance in a current flow between each of the source electrode 131 and the drain electrode 135 and the substrate 120 can be minimized.

Referring to FIG. 3, a gate insulator 134 may be disposed between the gate electrode 133 and the substrate 120. The gate insulator 134 may prevent a problem in that a control signal applied to the gate electrode 133 is transmitted to the substrate 120 and degrades the radio frequency (RF) performance of the transistor 130. Meanwhile, the gate electrode 133 may be Schottky-contacted to the substrate 120. In this case, the gate insulator 134 may not be disposed.

Referring to FIG. 3, in a case in which a control signal is applied to the gate electrode 133, when the control signal has high voltage, the active region 141 may be formed in the channel layer 140, and a current may flow between the source electrode 131 and the drain electrode 135, and when the control signal has low voltage, the active region 141 may disappear, and current movement between the source electrode 131 and the drain electrode 135 may be blocked. In addition, a degree of amplification of a signal output from the drain electrode 135 may be determined according to a magnitude of a voltage of a control signal applied to the gate electrode 133.

Here, the active region 141 may be formed in the channel layer 140 located between the source electrode 131 and the drain electrode 135. For example, a first dielectric (not shown) may be disposed below the source electrode 131, and a partial area of a lower surface of the source electrode 131 may be ohmic-contacted to the first dielectric (not shown). Similarly, a second dielectric (not shown) may be disposed below the drain electrode 135, and a partial area of a lower surface of the drain electrode 135 may be ohmic-contacted to the second dielectric (not shown). In addition, the active region 141 may be formed in an area of the channel layer 140 between the first dielectric (not shown) and the second dielectric (not shown).

High heat may be generated in the active region 141 due to a flow of current. In particular, when the transistor 130 operates at high power and a high frequency, heat generated in the active region 141 may further increase due to the switching operation of the transistor 130. Heat generated in this way may accumulate in the active region 141 or a vicinity thereof. Therefore, when the transistor 130 operates, a portion with the highest temperature in the semiconductor device 100 may be the active region 141. In addition, when the channel layer 140 includes a material with high thermal conductivity, such as GaN, heat generated in the active region 141 may spread to the entire channel layer 140.

Referring to FIGS. 1 and 3, the insulating layer 150 is disposed on the substrate 120 and covers the transistor 130. Specifically, the insulating layer 150 may include a lower horizontal extension portion in contact with the substrate 120, a second horizontal extension portion in contact with an upper surface of the source electrode 131, a third horizontal extension portion in contact with an upper surface of the gate electrode 133, a fourth horizontal extension portion in contact with an upper surface of the drain electrode 135, and an upper horizontal extension portion in contact with a lower surface of the upper metal layer 160, the temperature measuring pad 181, the gate pad 183, and the drain pad 185. In addition, the insulating layer 150 may include a first vertical extension portion in contact with a side surface of each of the source electrode 131 and the gate electrode 133, and a second vertical extension portion in contact with a side surface of each of the drain electrode 135 and the gate electrode 133.

Referring to FIGS. 1 and 3, the insulating layer 150 is disposed to cover the transistor 130, thereby preventing a problem in that an RF signal output from the transistor 130 is interfered with by external signals. For example, the insulating layer 150 can prevent an RF signal from being interfered with by a current leakage flowing inside the semiconductor device 100 or a signal used when measuring the temperature measuring pad 181, the gate pad 183, and the drain pad 185.

The insulating layer 150 may include a material having excellent high-frequency insulation and heat resistance. Specifically, the insulating layer 150 may include SiC, silicon oxide such as SiO₂, silicon nitride such as Si₃N₄, aluminum oxide such as Al₂O₃, aluminum nitride such as AlN, hafnium oxide such as HfO₂, or gallium oxide such as Ga₂O₃. In addition, the insulating layer 150 may include various materials. For example, the insulating layer 150 may include epoxy or diamond.

Referring to FIGS. 1 and 3, the upper metal layer 160 is disposed on the insulating layer 150. Specifically, the upper metal layer 160 may be disposed at an uppermost end portion of the semiconductor device 100 together with the temperature measuring pad 181, the gate pad 183, and the drain pad 185. In addition, the upper metal layer 160 may be disposed to cover an upper portion of the insulating layer 150 as much as possible while being spaced apart from the temperature measuring pad 181, the gate pad 183, and the drain pad 185.

The upper metal layer 160 may include a metal material. The upper metal layer 160 may be made of the same material as the lower metal layer 110. In addition, the upper metal layer 160 may be grounded like the lower metal layer 110 and may function as a ground electrode of the transistor 130. One of the lower metal layer 110 and the upper metal layer 160 may function as a ground electrode, or both may function as a ground electrode. In this way, the upper metal layer 160 may include the same material as the lower metal layer 110 and may perform the same function as a ground electrode. Accordingly, the upper metal layer 160 may also dissipate heat generated in the active region 141 like the lower metal layer 110. Thus, metal layers may be disposed at both upper and lower portions of the semiconductor device 100, thereby increasing an area that can be grounded and increasing an ability or efficiency capable of dissipating heat.

Referring to FIGS. 2 and 3, a resistor 170 may be disposed in the channel layer 140. In addition, the resistor 170 may be disposed to be spaced a predetermined distance apart from the transistor 130 and the active region 141. Accordingly, the RF performance of the transistor 130 may not be degraded by a signal generated when the resistance of the resistor 170 is measured.

Referring to FIGS. 2 and 3, an upper surface of the resistor 170 may be exposed at an upper surface of the substrate 120 to be in contact with the insulating layer 150. However, the position of the upper surface of the resistor 170 is not limited thereto. For example, the resistor 170 may be disposed inside the substrate 120 to be covered by a material constituting the substrate 120.

Meanwhile, a shape of the resistor 170 may vary. For example, the resistor 170 may have a protruding shape, that is, a mesa shape, through an etching process or may have a thin film shape through a deposition process.

Referring to FIG. 3, the resistor 170 may be thermally connected to the active region 141. In particular, when the channel layer 140 includes a material with high thermal conductivity, such as GaN, the resistor 170 may effectively receive heat generated in the active region 141 through the channel layer 140. Accordingly, a temperature of the resistor 170 may be changed according to a temperature of the active region 141.

The resistor 170 may have a linear temperature coefficient of resistance (TC). That is, a resistance value of the resistor 170 may be proportional to the temperature of the resistor 170. Accordingly, since the resistance value of the resistor 170 has a linear relationship with the temperature of the active region 141, the temperature of the active region 141 may be accurately estimated based on the resistance value of the resistor 170.

Referring to FIGS. 1 and 3, various pads 181, 183, and 185 for supplying signals to the transistor 130 or the resistor 170 or measuring electrical parameters may be disposed on an insulating layer 150. These pads 181, 183, and 185 may function as contact points for transmitting external electrical signals into the interior of the semiconductor device 100 or transmitting signals generated in the semiconductor device 100 to the outside. For this purpose, the pads 181, 183, and 185 may include a metal material such as aluminum, copper, or gold or a conductive alloy material.

Specifically, the temperature measuring pad 181 for measuring the resistance of the resistor 170 may be disposed directly on the insulating layer 150. The resistor 170 and the temperature measuring pad 181 may be electrically connected to each other. Accordingly, a user may measure the resistance of the resistor 170 through the temperature measuring pad 181.

In addition, the gate pad 183 and the drain pad 185 may also be disposed directly on the insulating layer 150. The gate electrode 133 and the gate pad 183 may be electrically connected to each other, and the drain electrode 135 and the drain pad 185 may also be electrically connected to each other. Accordingly, a user may transmit a control signal to the gate electrode 133 through the gate pad 183 and may receive an output signal generated by the drain electrode 135 through the drain pad 185.

Referring to FIG. 1, the upper metal layer 160, the temperature measuring pad 181, the gate pad 183, and the drain pad 185 may all be disposed on the insulating layer 150 and may be spaced apart from each other. Accordingly, the upper metal layer 160, the temperature measuring pad 181, the gate pad 183, and the drain pad 185 may be electrically separated from each other so as not to mutually interrupt electrical functions thereof.

In addition, according to the embodiment described above, the upper metal layer 160, the temperature measuring pad 181, the gate pad 183, and the drain pad 185 may all be flatly disposed at an upper end portion of the semiconductor device 100. In this case, when a plurality of semiconductor devices 100 are coupled in a three-dimensional stacked (3D integrated circuit (IC)) structure, upper and lower end portions of the plurality of semiconductor devices 100 may be easily coupled. In this case, the lower metal layer 110 of an upper side semiconductor device 100 may be replaced with the upper metal layer 160 of a lower side semiconductor device 100.

Referring to FIG. 1, an area of the upper metal layer 160 may be half or more of an area of the substrate 120. Here, the area of the substrate 120 may be equal to an area of the insulating layer 150. Accordingly, the area of the upper metal layer 160 is greater than an area of portions other than the upper metal layer 160. That is, the area occupied by the upper metal layer 160 according to a plan view is greater than an area occupied by the temperature measuring pad 181, the gate pad 183, and the drain pad 185. According to the embodiment described above, the lower metal layer 110, the transistor 130, and the pads 181, 183, and 185 may be vertically disposed with at least one layer interposed therebetween, and thus the semiconductor device 100 may have a small area and stable RF performance, and at the same time, an area of the upper metal layer 160 may be maximized to maximize heat dissipation performance.

Referring to FIG. 3, the semiconductor device 100 may include a plurality of vias 191, 192, 193, and 194. Each of the vias 191, 192, 193, and 194 may extend in a direction perpendicular to a planar surface of the substrate 120.

Each of the vias 191, 192, 193, and 194 may include an electrically conductive material. For example, the vias 191, 192, 193, and 194 may include a metal material deposited inside a hole. In this case, the vias 191, 192, 193, and 194 may be through-silicon vias (TSVs).

In some cases, each of the vias 191, 192, 193, and 194 may include a thermally conductive material. For example, the vias 191, 192, 193, and 194 may include a thermally conductive epoxy, aluminum nitride, boron nitride, silicon oxide mixed with a thermally conductive filler or polyimide which is filling the hole.

Referring to FIG. 3, the first via 191 may vertically pass through the substrate 120 between the lower surface of the source electrode 131 and an upper surface of the lower metal layer 110. In addition, the first via 191 may be disposed to be spaced apart from the active region 141. As described above, when the active region 141 is formed between the first dielectric (not shown) and the second dielectric (not shown), the first via 191 may pass through the substrate 120 from an area, in which the first dielectric (not shown) is not present, to the lower metal layer 110. In this case, the first via 191 may electrically or thermally connect the source electrode 131 to the lower metal layer 110 without interrupting a flow of electrons moving in the active region 141.

When the first via 191 includes an electrically conductive material, the source electrode 131 and the lower metal layer 110 may be electrically connected to each other. Therefore, when the lower metal layer 110 is grounded, the source electrode 131 may also be grounded. In this case, in the semiconductor device 100, a source pad for applying an electric signal to the source electrode 131 may not be present.

The first via 191 includes a thermally conductive material. Accordingly, the source electrode 131 and the lower metal layer 110 are thermally connected to each other. Accordingly, heat generated in the active region 141 may be transferred to the lower metal layer 110 through the first via 191 disposed adjacent to the active region 141 to be dissipated to the outside.

Referring to FIG. 3, the second via 192 may vertically pass through the insulating layer 150 between the upper surface of the source electrode 131 and the lower surface of the upper metal layer 160.

When the second via 192 includes an electrically conductive material, the source electrode 131 and the upper metal layer 160 may be electrically connected to each other. Therefore, when the upper metal layer 160 is grounded, the source electrode 131 may also be grounded. In this case, in the semiconductor device 100, a source pad for applying an electric signal to the source electrode 131 may not be present. That is, the source pad may be replaced with the upper metal layer 160 that serves as a ground electrode. Accordingly, a size of the semiconductor device 100 may be further reduced by reducing an area of the upper metal layer 160 together with areas of the temperature measuring pad 181, the gate pad 183, and the drain pad 185 on an upper surface of the semiconductor device 100.

Like the first via 191, the second via 192 also includes a thermally conductive material. Accordingly, the source electrode 131 and the upper metal layer 160 are thermally connected to each other. Accordingly, heat generated in the active region 141 may be transferred to the upper metal layer 160 through the source electrode 131 and the second via 192 to be dissipated to the outside.

According to the embodiment described above, heat generated in the active region 141, which is a heat source generating the most heat in the semiconductor device 100, may be conducted in both directions through the first via 191 and the second via 192 disposed adjacent to the active region 141 to be dissipated from each of the lower metal layer 110 and the upper metal layer 160. Accordingly, the semiconductor device 100 may have excellent heat dissipation performance. In addition, since the semiconductor device 100 directly dissipates heat from the heat source generating the greatest heat, it is possible to prevent performance degradation and a decrease in lifetime.

In addition, in the semiconductor device 100, without a separate additional component, the lower metal layer 110 and the upper metal layer 160 functioning as ground electrodes of the source electrode 131 and vias generally used in semiconductor devices 100 are used to dissipate heat, thereby achieving a small volume and low manufacturing costs.

Referring to FIG. 3, the third via 193 may vertically pass through the insulating layer 150 between the lower surface of the temperature measuring pad 181 and the upper surface of the resistor 170. When the third via 193 includes an electrically conductive material, the resistor 170 and the temperature measuring pad 181 may be electrically connected to each other. Therefore, a user may measure a resistance value of the resistor 170 by measuring a current or voltage of the temperature measuring pad 181.

Referring to FIG. 3, the fourth via 194 may vertically pass through the substrate 120 between a lower surface of the resistor 170 and the upper surface of the lower metal layer 110.

When the fourth via 194 includes an electrically conductive material, the lower metal layer 110 and the resistor 170 may be electrically connected to each other. Therefore, when the lower metal layer 110 is grounded, the resistor 170 may also be grounded. In this case, since a grounded probe is not required to measure the resistance of the resistor 170, a user may measure the resistance of the resistor 170 by bringing only one probe into contact with the temperature measuring pad 181.

When the fourth via 194 includes a thermally conductive material, the lower metal layer 110 and the resistor 170 may be thermally connected to each other. Accordingly, heat energy generated in the active region 141 and conducted to the lower metal layer 110 through the first via 191 may be conducted to the resistor 170 through the fourth via 194. Accordingly, the resistor 170 may receive heat generated in the active region 141 from the lower metal layer 110 as well as the channel layer 140. In this way, since the resistor 170 may receive heat generated in the active region 141 in two directions, a temperature of the resistor 170 may be very similar to a temperature of the active region 141. Therefore, a user may estimate the temperature of the active region 141 with high accuracy by measuring the resistance value of the resistor 170.

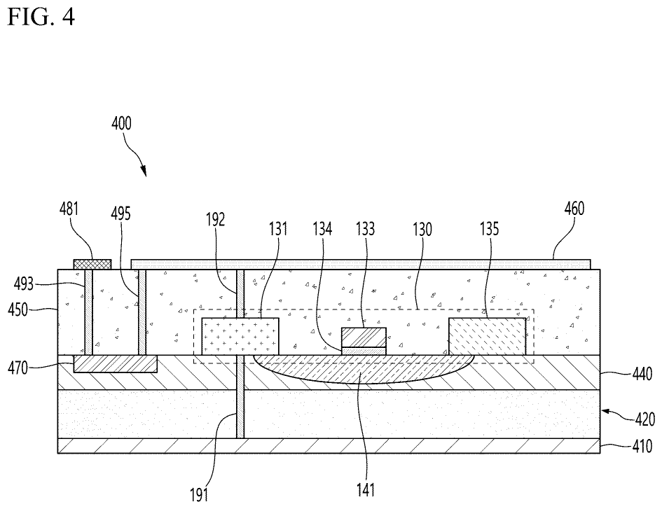

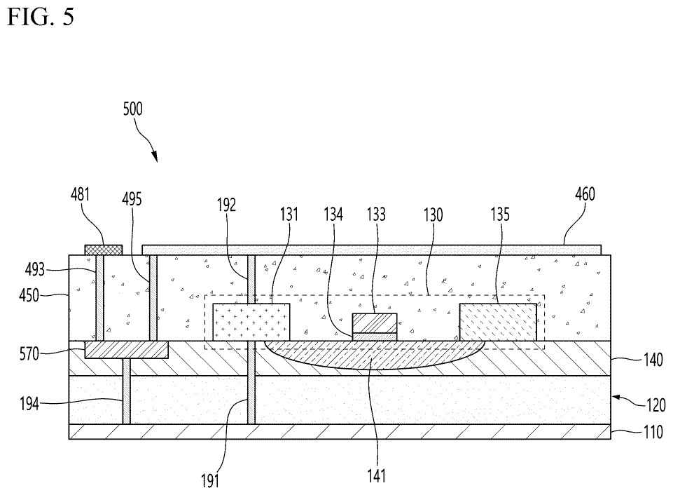

Meanwhile, the resistor 170 may receive heat generated in the active region 141 not only through the lower metal layer 110 but also through the upper metal layer 160. This will be described with reference to FIGS. 4 and 5.

FIG. 4 is a cross-sectional view of a semiconductor device according to another embodiment of the present disclosure. FIG. 5 is a cross-sectional view of a semiconductor device according to still another embodiment of the present disclosure.

Referring to FIG. 4, a semiconductor device 400 may include a fifth via 495. The fifth via 495 may vertically pass through an insulating layer 450 between an upper surface of a resistor 470 and a lower surface of an upper metal layer 460. For such a structure, the upper metal layer 460 may have a wider area than the upper metal layer 160 shown in FIG. 3, and a temperature measuring pad 481 may have a narrower area than the temperature measuring pad 181 shown in FIG. 3.

When the fifth via 495 includes an electrically conductive material, the upper metal layer 460 and the resistor 470 may be electrically connected to each other. Therefore, when the upper metal layer 460 is grounded, the resistor 470 may also be grounded. In this case, since a grounded probe is not required to measure the resistance of the resistor 470, a user may measure the resistance of the resistor 470 by bringing only one probe into contact with the temperature measuring pad 481.

When the fifth via 495 includes a thermally conductive material, the upper metal layer 460 and the resistor 470 may be thermally connected to each other. Accordingly, heat energy generated in an active region 141 and conducted to the upper metal layer 460 through a second via 192 may be conducted to the resistor 470 through the fifth via 495. Accordingly, since the resistor 470 receives heat generated in the active region 141 from the upper metal layer 460 as well as a channel layer 440, a temperature of the resistor 470 may become very similar to a temperature of the active region 141. Therefore, a user may estimate the temperature of the active region 141 with high accuracy by measuring a resistance value of the resistor 470.

Referring to FIG. 5, a semiconductor device 500 may include both a fourth via 194 and a fifth via 495. In such a case, both the fourth via 194 and the fifth via 495 may include a thermally conductive material. Accordingly, the heat dissipation performance of the semiconductor device 500 can be further enhanced.

In addition, both a lower metal layer 110 and an upper metal layer 460 may function as ground electrodes. As described above, when a plurality of semiconductor devices 500 are stacked to form a 3D IC structure, an upper metal layer 460 of a lower side semiconductor device 500 may perform a function of a lower metal layer 110 of an upper side semiconductor device 500. In this case, when the fourth via 194 and the lower metal layer 110, and the fifth via 495 and the upper metal layer 460 perform the same function and are symmetrically disposed as provided in the present embodiment, there can be ease in implementing a 3D IC structure using the plurality of semiconductor devices 500.

A semiconductor device according to any one of the problem-solving means of the present disclosure can have excellent heat dissipation performance by dissipating internally generated heat from each of upper and lower metal layers having a large area.

In a semiconductor device according to any one of the problem-solving means of the present disclosure, heat of an active region is dissipated through a via disposed adjacent to the active region which is a heat source generating the greatest heat, thereby preventing the performance degradation and preventing a decrease in lifetime.

A semiconductor device according to any one of the problem-solving means of the present disclosure can have a small volume and low manufacturing costs by dissipating heat generated in a device by using components used for the operation of a transistor without a separate additional component.

Since a semiconductor device according to any one of the problem-solving means of the present disclosure has a flat upper end shape, when a plurality of semiconductor devices are coupled in a three-dimensional stacked structure, an upper end portion and a lower end portion of each of the plurality of semiconductor devices can be easily coupled.

A semiconductor device according to any one of the problem-solving means of the present disclosure can have a small area and stable RF performance by including a lower metal layer, a transistor, and pads vertically disposed with at least one layer interposed therebetween.

Although embodiments of the present disclosure have been described in more detail with reference to the accompanying drawings, the present disclosure is not necessarily limited to these embodiments, and various modifications may be made without departing from the technical spirit of the present disclosure. Accordingly, the embodiments disclosed in the present disclosure are not intended to limit the technical idea of the present disclosure, but are for illustrative purposes, and the scope of the technical idea of the present disclosure is not limited by these embodiments. Accordingly, it should be understood that the above-described embodiments are exemplary in all respects and not restrictive. The spirit and scope of the present disclosure should be interpreted by the appended claims and encompass all equivalents thereof falling within the scope of the appended claims.

What is claimed is:

1. A semiconductor device comprising:
a lower metal layer;
a substrate disposed on the lower metal layer;
at least one transistor disposed on the substrate;
an insulating layer disposed on the substrate and configured to cover the at least one transistor;
an upper metal layer disposed on the insulating layer;
a first via which includes a material having thermal conductivity; and
a second via which includes a material having thermal conductivity,
wherein a source electrode of the at least one transistor is connected to the lower metal layer through the first via and is connected to the upper metal layer through the second via.

2. The semiconductor device of claim 1, further comprising:
a resistor;
a third via which includes a material having electrical conductivity; and
a temperature measuring pad disposed on the insulating layer,
wherein the resistor is connected to the temperature measuring pad through the third via.

3. The semiconductor device of claim 2, further comprising a fourth via which includes a material having thermal conductivity,
wherein the resistor is connected to the lower metal layer through the fourth via.

4. The semiconductor device of claim 2, further comprising a fifth via which includes a material having thermal conductivity,
wherein the resistor is connected to the upper metal layer through the fifth via.

5. The semiconductor device of claim 2, wherein the resistor is disposed in a layer of the substrate in which an active region of the at least one transistor is formed.

6. The semiconductor device of claim 2, further comprising:
a gate pad electrically connected to a gate electrode of the at least one transistor; and
a drain pad electrically connected to a drain electrode of the at least one transistor,
wherein the upper metal layer, the temperature measuring pad, the gate pad, and the drain pad are disposed on the insulating layer.

7. The semiconductor device of claim 6, wherein the upper metal layer, the temperature measuring pad, the gate pad, and the drain pad are spaced apart from each other, and
an area of the upper metal layer is half or more of an area of the substrate.

8. The semiconductor device of claim 1, wherein the substrate includes a compound.

9. The semiconductor device of claim 8, wherein a layer of the substrate in which an active region of the at least one transistor is formed includes gallium nitride (GaN).
